(19) United States
(12) Patent Application Publication
(10) Pub. No.: US 2009/0020316 A1
(43) Pub. Date: Jan. 22, 2009

(54) METHOD OF MANUFACTURING CHIP ON FILM AND STRUCTURE THEREOF

(76) Inventors: Chia-Hui Wu, Tainan County (TW); Pai-Sheng Cheng, Tainan County (TW); Po-Chiang Tseng, Tainan County (TW)

Correspondence Address: NORTH AMERICA INTELLECTUAL PROPERTY CORPORATION, P.O. BOX 506, MERRIFIELD, VA, 22116, US

(21) Appl. No.: 12/033,876

(22) Filed: Feb. 19, 2008

Related U.S. Application Data
(60) Provisional application No. 60/950,872, filed on Jul. 19, 2007.

(51) Int. Cl. H05K 1/00; H05K 3/00

(52) U.S. Cl. 174/252; 29/846

(57) ABSTRACT

A method of manufacturing a chip on film (COF) is provided, including: providing a flexible circuit board; and forming a plurality of leads on the flexible circuit board. Each of the leads has a thickness of 8 um˜15 um and a cross-section shape is substantially rectangular. A COF structure, having a flexible circuit board and a plurality of leads formed on the flexible circuit board, is provided. Each lead has a thickness of 8 um˜15 um, and lead widths of the leads are based on pitch widths of a plurality of bumps corresponding to the leads. A COF structure, having a flexible circuit board and a plurality of leads formed on the flexible circuit board. Each of the leads has a thickness of 8 um˜15 um, and a lead width of each of the leads is greater than a bump width minus 4 um.

### CROSS REFERENCE TO RELATED APPLICATIONS

This application claims the benefit of U.S. provisional application No. 60/950,872, which was filed on Jul. 19, 2007.

### BACKGROUND OF THE INVENTION

1. Field of the Invention

The present invention relates to a chip on film (COF), and more particularly, to a method of manufacturing a COF and a structure thereof.

2. Description of the Prior Art

In recent years, liquid crystal display (LCD) screens have been in widespread use in all kinds of electronic apparatus such as mobile phones, personal digital assistants (PDAs) and notebooks. As the size of display screens increases, light and thin liquid crystal display devices are being substituted for traditional display devices such as cathode ray tube (CRTs), and therefore play an increasingly important role in the display field.

As the size of LCD gets larger, the number of channels for the driver integration circuit and the operation frequency are substantially increased. However, with the increase on the number of channels for the driver IC and the operation frequency, the performance and the lifetime of the device might be reduced due to unduly overheated of the driver IC. Thus, it is therefore desired to provide methods and apparatus for improving thermal dissipation and reducing overheated on the IC of the liquid crystal display devices.

### SUMMARY OF THE INVENTION

It is therefore one of the objectives of the present invention to provide a method of manufacturing a COF and a structure thereof for improving thermal dissipation, in order to solve the above-mentioned problem.

According to an exemplary embodiment of the present invention, a method of manufacturing a COF is disclosed. The method comprises: providing a flexible circuit board; and forming a plurality of leads on the flexible circuit board, wherein each of the leads has a thickness of 8 um˜15 um and a cross-section shape that is substantially rectangular.

According to an exemplary embodiment of the present invention, a COF structure is also disclosed. The COF structure comprises: a flexible circuit board; and a plurality of leads, formed on the flexible circuit board, wherein each of the leads has a thickness of 8 um˜15 um, and lead widths of the leads are based on pitch widths of a plurality of bumps corresponding to the leads.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a plan view illustrating a chip on film (COF) structure according to an embodiment of the present invention.

FIG. 2 is a sectional view taken along line A-A′ shown in FIG. 1.

FIG. 3 is a sectional view of the inner leads taken along line B-B′ shown in FIG. 1.

FIG. 4 is a sectional view illustrating the cross-section shape of the conventional inner lead and the cross-section shape of the inner lead in the COF structure shown in FIG. 1.

FIG. 5 is a plan view illustrating the relation between a bump width and a conventional inner lead width and the relation between the bump width and the inner lead width in the COF structure shown in FIG. 1.

FIG. 6 is a diagram illustrating a first surface of the flexible circuit board having a used area and a dummy area.

FIG. 7 is a diagram illustrating a second surface of the flexible circuit board having a dummy area.

### DETAILED DESCRIPTION

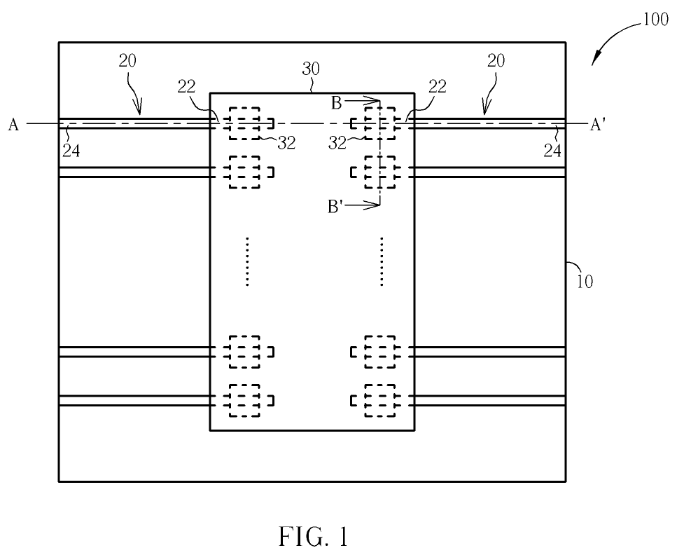

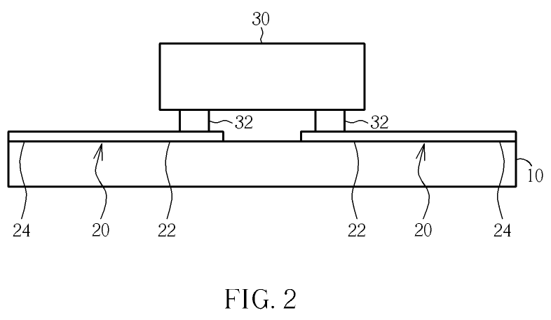

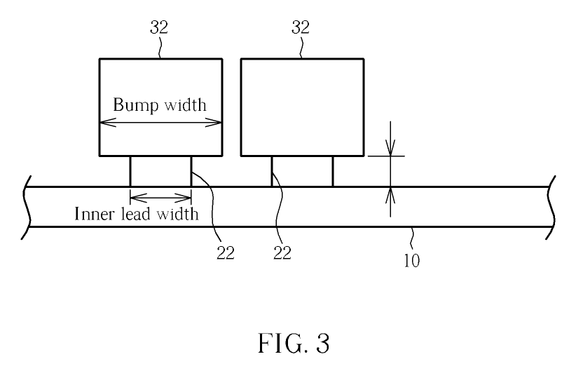

Please refer to FIG. 1 in conjunction with FIG. 2. FIG. 1 is a plan view illustrating a chip on film (COF) structure 100 according to an embodiment of the present invention. FIG. 2 is a sectional view taken along line A-A′ shown in FIG. 1. As shown in FIG. 1 and FIG. 2, the COF structure 100 comprises a flexible circuit board 10 such as a flexible printed circuit (FPC) board, a plurality of connection wires 20 and a chip 30. A plurality of inner leads 22 extend from one end of the connection wires 20 and are electrically connected with a plurality of bumps 32 on the chip 30. A plurality of outer leads 24 extend from another end of the connection wires 20 and are electrically connected with a plurality of pad electrodes (not shown in FIG. 1 and FIG. 2) which transmit, for example, driving signal or power supply voltage signal to signal lines. The inner leads 22 and outer leads 24 are composed of the connection wires 20. Please refer to FIG. 3. FIG. 3 is a sectional view of the inner leads 22 taken along line B-B′ shown in FIG. 1. As shown in FIG. 3, each of the inner leads 22 has a thickness of 8 um˜15 um.

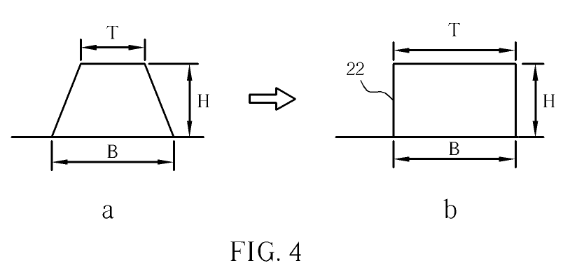

In order to solve the above mentioned heat dissipation problem, the present invention proposes enlarging the cross-section area of the inner lead 22 since it can improve thermal dissipation and reduce the heat effect generated from the chip 30. Please refer to FIG. 4. A sub-diagram a in FIG. 4 shows a sectional view illustrating the cross-section shape of the conventional inner lead. A sub-diagram b in FIG. 4 shows a sectional view illustrating the cross-section shape of the inner lead 22 in the COF structure 100 shown in FIG. 1. As can be seen from the diagram, the cross-section shape of the conventional inner lead formed by using a subtractive process is trapezoidal. In the preferred embodiment of the present invention, the cross-section shape of the inner lead 22 formed by using a semi-additive process, anisotropic process or the like is approximately rectangular. Supposing that etching factor=2H/(B−T), in which the parameters H, B and T are defined as indicated in FIG. 4, since T is approximately equal to B for the cross-section shape of the inner lead 22, as shown in sub-diagram b, the etching factor for the inner lead formed by using new process is far larger than one. The advantage of using a rectangular shape for the cross-section rather than the traditional trapezoidal shape is to have a larger cross-section area, as shown in FIG. 4, so that the thermal dissipation efficiency can be significantly increased and the heat effect can be significantly alleviated, which are two of the most important objectives of the present invention. Please note that the above description is only for illustrative purposes, and is not a limitation of the present invention. In practice, using any process for enlarging the cross-section area of the inner lead in order to increase thermal dissipation efficiency also obeys the spirit of the present invention.

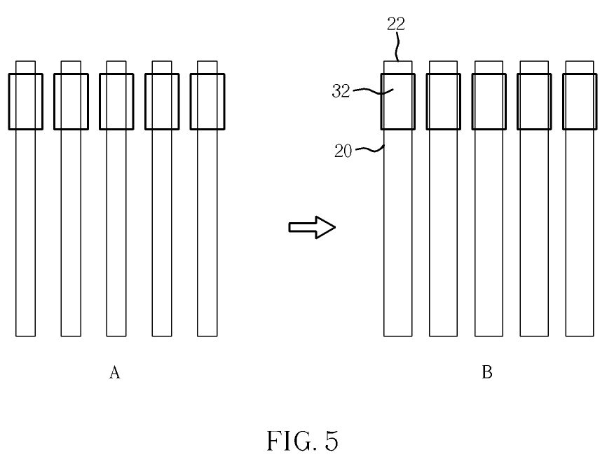

In another aspect of the present invention, the design of the inner lead width is also important for thermal dissipation. The inner lead width and bump width are illustrated in FIG. 3. In general, a wider inner lead width can improve thermal dissipation. Please refer to FIG. 5. A sub-diagram A in FIG. 5 shows a plan view illustrating the relation between a bump width and a conventional inner lead width. A sub-diagram B in FIG. 5 shows a plan view illustrating the relation between the bump width and the inner lead width in the COF structure 100 shown in FIG. 1. As shown in FIG. 5, the inner lead 22 in the COF structure 100 has a wider width than the conventional inner lead. There are some limitations for widening the inner lead width, however. For example, each of the inner lead widths may be designed to be greater than the corresponding bump width minus 4 um, respectively. This is not intended to limit the scope of the invention, however, and is merely one example of various modifications and similar arrangements (as would be apparent to those skilled in the art). For example, in some cases, the inner lead width is based on the pitch widths of the plurality of bumps to be designed.

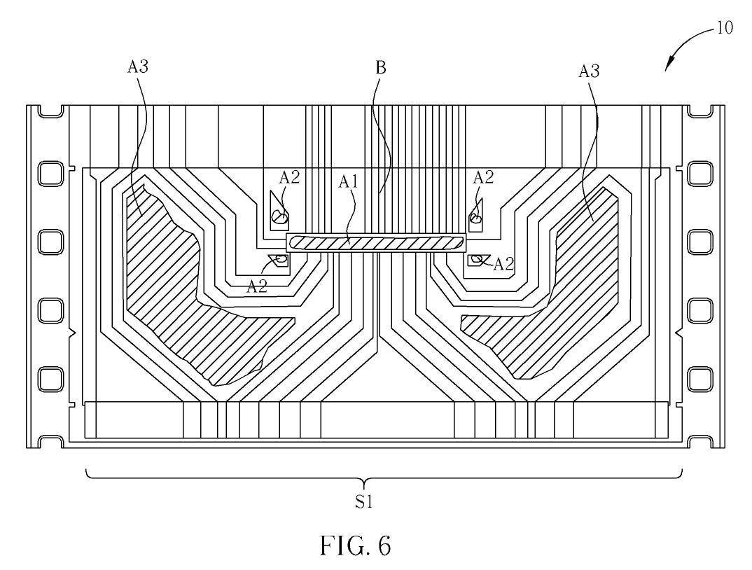

In addition, covering a thermal dissipation material (e.g. Cu) on a dummy area, which has no leads or connection wires formed thereon, increases the efficiency of thermal dissipation. Please refer to FIG. 6. FIG. 6 is a diagram illustrating a first surface SI of the flexible circuit board 10 having a used area and a dummy area. The connection wires 20 in FIG. 1 are formed in the used area, including trace area B, on the flexible circuit board 10. In this embodiment, the dummy area, including the area A1 underneath device IC, device corner area A2 and space of trace area A3 on the first surface S1 are covered with the thermal dissipation material (represented by oblique lines) without affecting the transmission of driving signals or power supply voltage signals of the chip 30 via signal lines. Since the areas A1, A2 and A3 should be well known by those skilled in the art, further description is omitted here for the sake of brevity.

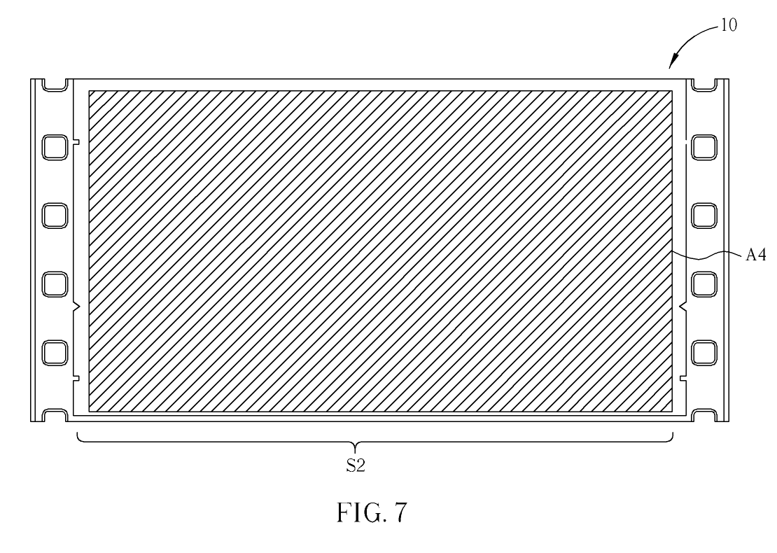

Furthermore, in the preferred embodiment of the present invention, a second surface S2 of the flexible circuit board 10 opposite to the first surface S1, on which there are no any leads or connection wires, is also covered with the thermal dissipation material in order to help the chip 30 with thermal dissipation. As shown in FIG. 7, an unused area A4 is covered with thermal dissipation material (represented by oblique lines). It should be noted that the size, shape, and location of the unused area A4 are not limited to the configuration shown in FIG. 7.

In the above description, dummy areas on two surfaces of the flexible circuit board 10 are covered with the thermal dissipation material, but this is only a preferred embodiment of the present invention. In other embodiments of the present invention, a dummy area on only one surface of the flexible circuit board being covered with the thermal dissipation material is workable. The same objective of improving heat dissipation efficiency is achieved. For example, only the device corner area is covered with the thermal dissipation material, or only the surface having no leads or connection wires formed thereon is covered with the thermal dissipation material. These modifications also fall within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing a chip on film (COF), comprising:
providing a flexible circuit board having a first surface and a second surface opposite to the first surface; and
forming a plurality of leads on the first surface of the flexible circuit board, wherein each of the lead has a thickness of 8 um˜15 um and a cross-section shape being substantially rectangular.

2. The method of claim 1, wherein the leads are formed by a Semi-Additive Process or an Anisotropic Process.

3. The method of claim 1, wherein the step of forming the leads further comprises determining lead widths of the leads according to pitch widths of a plurality of bumps corresponding to the leads.

4. The method of claim 3, further comprising:
forming a first thermal dissipation layer on a first dummy area of the first surface of the flexible circuit board by a thermal dissipation material, wherein the first dummy area has no lead formed thereon.

5. The method of claim 3, further comprising:
forming a second thermal dissipation layer on a second dummy area of the second surface of the flexible circuit board by a thermal dissipation material.

6. The method of claim 1, wherein the step of forming the leads further comprises:
determining a lead width of each of the leads to be greater than a bump width minus 4 um.

7. The method of claim 6, further comprising:
forming a first thermal dissipation layer on a first dummy area of the first surface of the flexible circuit board by a thermal dissipation material.

8. The method of claim 6, further comprising:
forming a second thermal dissipation layer on a second dummy area of the second surface of the flexible circuit board by a thermal dissipation material.

9. A chip on film (COF) structure, comprising:
a flexible circuit board having a first surface and a second surface opposite to the first surface; and
a plurality of leads, formed on the first surface of the flexible circuit board, wherein each of the leads has a thickness of 8 um˜15 um, and lead widths of the leads are based on pitch widths of a plurality of bumps corresponding to the leads.

10. The COF structure of claim 9, wherein a cross-section shape of each of the leads is substantially rectangular.

11. The COF structure of claim 10, wherein the flexible circuit board has a first dummy area on the first surface of the flexible circuit board and covered by a thermal dissipation material.

12. The COF structure of claim 10, wherein the flexible circuit board has a second dummy area on the second surface of the flexible circuit board and covered by a thermal dissipation material.

13. A chip on film (COF) structure, comprising:
a flexible circuit board having a first surface and a second surface opposite to the first surface; and
a plurality of leads, formed on the first surface of the flexible circuit board, wherein each of the leads has a thickness of 8 um˜15 um, and a lead width of each of the leads is greater than a bump width minus 4 um.

14. The COF structure of claim 13, wherein a cross-section shape of each of the leads is substantially rectangular.

15. The COF structure of claim 14, wherein the flexible circuit board has a first dummy area on the first surface of the flexible circuit board and covered by a thermal dissipation material.

16. The COF structure of claim 14, wherein the flexible circuit board has a second dummy area on the second surface of the flexible circuit board and covered by a thermal dissipation material.
